(19) United States
(12) Patent Application Publication
(10) Pub. No.: US 2025/0118344 A1
(43) Pub. Date: Apr. 10, 2025

(54) SERIAL PASS-THROUGH TECHNIQUES FOR MEMORY DEVICE INTERFACES

(71) Applicant: Micron Technology, Inc., Boise, ID (US)

(72) Inventors: Stephen Hanna, Fort Collins, CO (US); Jonathan S. Parry, Boise, ID (US)

(21) Appl. No.: 18/774,431

(22) Filed: Jul. 16, 2024

Related U.S. Application Data
(60) Provisional application No. 63/587,962, filed on Oct. 4, 2023.

(51) Int. Cl. G11C 7/10; G11C 29/52

(52) U.S. Cl. CPC G11C 7/1096; G11C 7/1057; G11C 29/52

(57) ABSTRACT

Methods, systems, and devices for serial pass-through techniques for memory device interfaces are described. Memory interface circuitry may be configured to receive a command via a first interface having a first set of terminals to configure the memory interface circuitry for a pass-through mode. As part of the pass-through mode, the memory interface circuitry may receive data from an external device via the first interface and output the data to one or more memory devices via a second interface having a second set of terminals. In some examples, the received data may be associated with a write burst, in which the memory interface circuitry may serially receive multiple portions of the data to write to a buffer of the memory interface circuitry. After reaching a threshold quantity of data, the buffer may output the portions of the data to the one or more memory devices via the second interface.

### CROSS REFERENCE

The present application for patent claims priority to U.S. Patent Application No. 63/587,962 by Hanna et al., entitled “SERIAL PASS-THROUGH TECHNIQUES FOR MEMORY DEVICE INTERFACES,” filed Oct. 4, 2023, which is assigned to the assignee hereof, and which is expressly incorporated by reference in its entirety herein.

### TECHNICAL FIELD

The following relates to one or more systems for memory, including serial pass-through techniques for memory device interfaces.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports serial pass-through techniques for memory device interfaces in accordance with examples as disclosed herein.

FIG. 2 shows an example of memory interface circuitry that supports serial pass-through techniques for memory device interfaces in accordance with examples as disclosed herein.

FIG. 3 shows an example of a timing diagram that supports serial pass-through techniques for memory device interfaces in accordance with examples as disclosed herein.

FIG. 4 shows an example of a memory interface architecture that supports serial pass-through techniques for memory device interfaces in accordance with examples as disclosed herein.

FIG. 5 shows a block diagram of a memory interface that supports serial pass-through techniques for memory device interfaces in accordance with examples as disclosed herein.

FIGS. 6 and 7 show flowcharts illustrating methods that support serial pass-through techniques for memory device interfaces in accordance with examples as disclosed herein.

### DETAILED DESCRIPTION

Some memory systems may implement a first interface, such as an open NAND flash interface (ONFI), to support communication between a memory system controller and one or more memory devices of the memory system. Additionally, or alternatively, some memory systems may implement a second interface, such as a separate command address (SCA) interface, which may be alternatively referred to as a separate command interface or an independent command address (iCAD) interface, to support communication between the memory system (e.g., one or more memory devices of the memory system) and an external device, such as a host system or tester device. In some examples, the second interface may support a pass-through mode to allow an external device to directly access one or more memory devices (e.g., raw NAND) of the memory system, which may include bypassing components of a memory system controller. Such a pass-through mode may support various functionality, such as allowing a manufacturer or integrator to test memory devices without implementing or accessing additional firmware that communicates with a memory system controller. Further, such a pass-through mode may allow relatively less-complex devices (e.g., devices associated with a downgraded market) to access memory devices without operating or otherwise implementing a relatively more-complex memory system controller (e.g., omitting a memory system controller). However, some implementations of a second interface may support limited accessibility to memory devices (e.g., may not support a pass-through mode to bypass aspects of a memory system controller).

As described herein, memory interface circuitry may be operable to couple with one or more memory devices and support a serial pass-through mode for accessing the one or more memory devices. For example, the memory interface circuitry may be configured to receive a command, via a first interface having a first set of terminals (e.g., an SCA interface), to configure the memory interface circuitry for a pass-through mode (e.g., a serial pass-through mode (SPTM)). As part of the pass-through mode, the memory interface circuitry may be configured to receive data from an external device via the first interface and output the data to the one or more memory devices via a second interface having a second set of terminals (e.g., an ONFI interface). In some examples, the received data may be associated with a write burst, for which the memory interface circuitry may serially receive multiple (e.g., two or more) portions of the data to write to a buffer of the memory interface circuitry. After reaching a threshold quantity of data, the buffer may output the portions of the data to the one or more memory devices via the second interface (e.g., concurrently, in parallel). In such examples, the memory interface circuitry may output the portions of data based on the buffer storing a threshold quantity of data (e.g., in response to or otherwise based on the buffer becoming full). Configuring the memory interface circuitry to support the pass-through mode may allow the external device to bypass aspects of a memory system controller and, accordingly, may provide an external device direct access to the one or more memory devices in accordance with a simplified interface (e.g., using fewer terminals, in accordance with a reduced command set, in accordance with a reduced clock rate or data rate, in accordance with a reduced capability) relative to other interfaces.

In addition to applicability in memory systems as described herein, techniques for serial pass-through techniques for memory device interfaces may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by allowing for increased flexibility of types of testing devices, which may increase adaptability and use-cases of electronic systems, among other benefits.

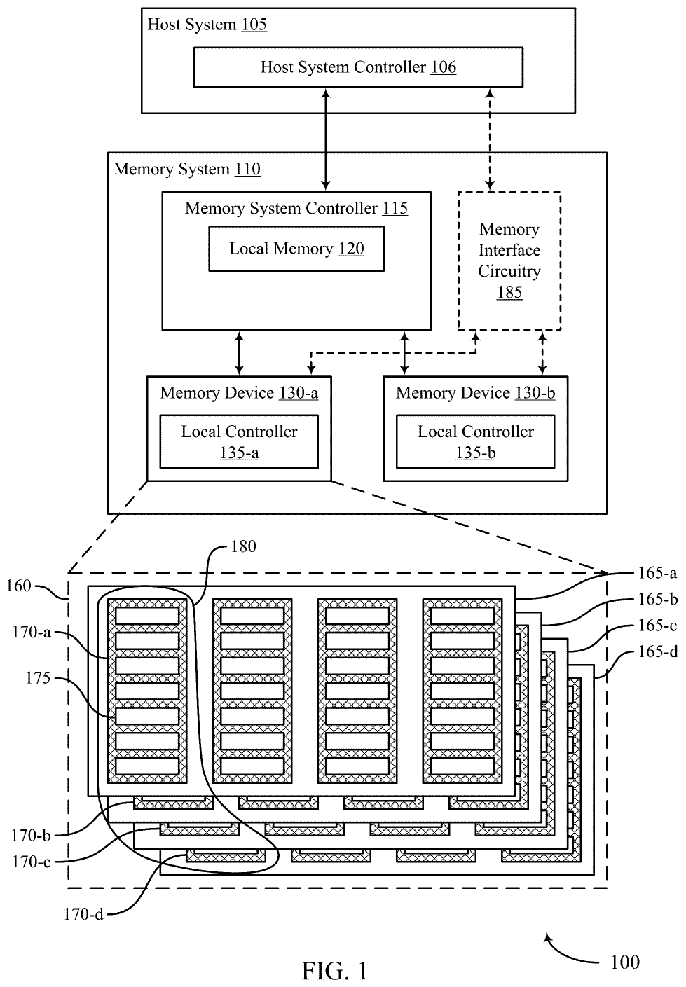

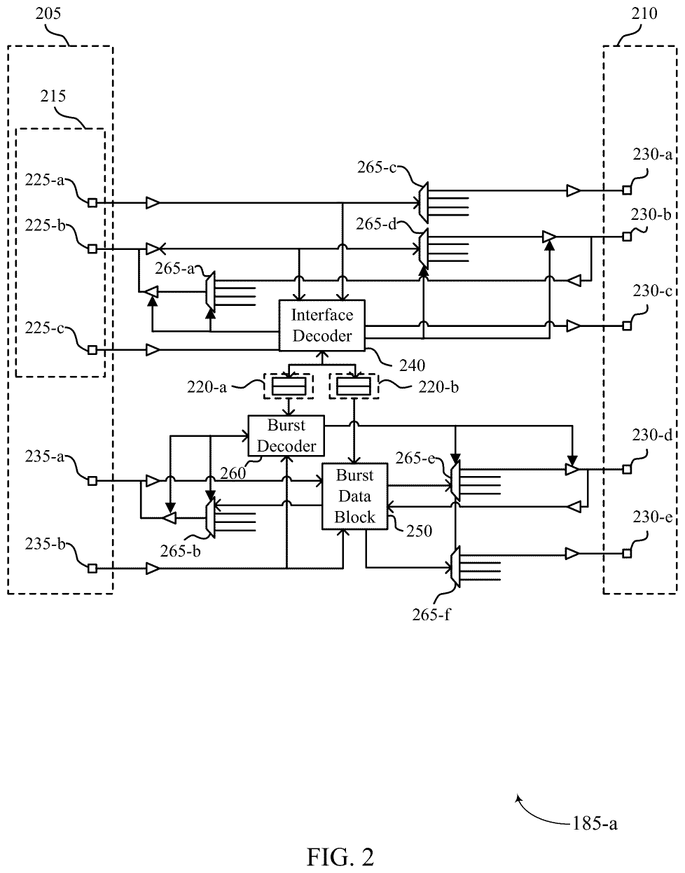

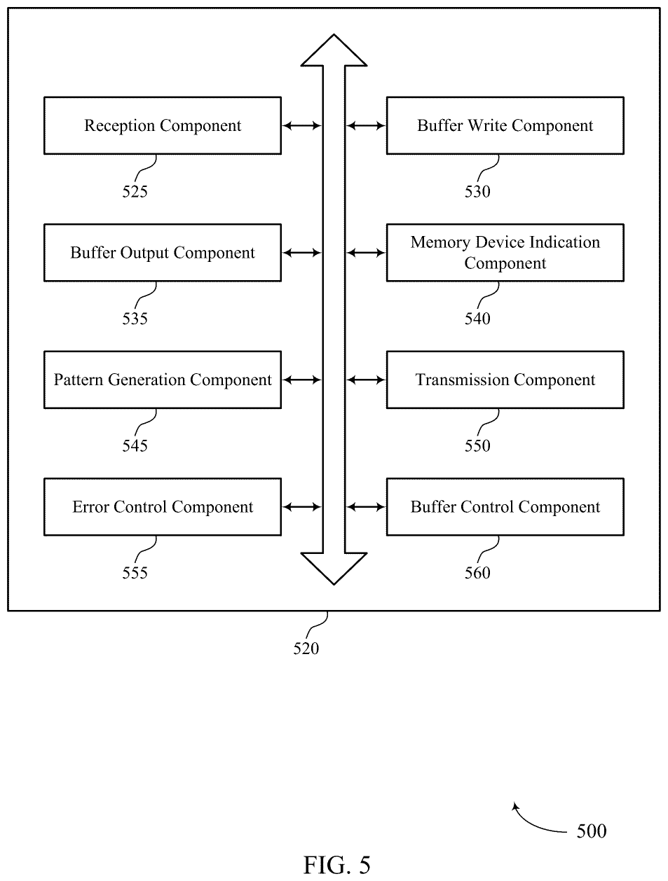

Features of the disclosure are initially described in the context of systems and devices with reference to FIG. 1. Features of the disclosure are described in the context of memory interface circuitry and a timing diagram with reference to FIGS. 2 through 4. These and other features of the disclosure are further illustrated by and described in the context of an apparatus diagram and flowchart that relate to serial pass-through techniques for memory device interfaces with reference to FIGS. 5 through 7.

FIG. 1 shows an example of a system 100 that supports serial pass-through techniques for memory device interfaces in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, an SCA interface, an iCAD interface, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some cases, a memory system 110 may implement a first interface, such as an ONFI, to support communication between a memory system controller 115 and one or more memory devices 130 of the memory system 110. Additionally, or alternatively, a memory system 110 may implement a second interface, such as an SCA interface, which may be alternatively referred to as a separate command interface or an iCAD interface, to support communication between the memory system 110 (e.g., one or more memory devices 130 of the memory system 110) and an external device, such as a host system 105 or tester device. In some examples, the second interface may support a pass-through mode to allow an external device to directly access one or more memory devices 130 (e.g., raw NAND) of the memory system 110, which may include bypassing components of a memory system controller 115. Such a pass-through mode may support various functionality, such as allowing a manufacturer or integrator to test memory devices without implementing additional firmware that communicates with a memory system controller 115. Further, such a pass-through mode may allow relatively less-complex devices (e.g., devices associated with a downgraded market) to access memory devices 130 without operating or otherwise implementing a relatively more-complex memory system controller 115 (e.g., omitting a memory system controller 115). However, some implementations of a second interface may support limited accessibility to memory devices 130 (e.g., may not support a pass-through mode to bypass aspects of a memory system controller 115).

In accordance with examples as described herein, memory interface circuitry 185 may be configured to couple with one or more memory devices 130, which may support direct access to the memory devices 130. The memory interface circuitry 185 may be operable to couple with an external device (e.g., a tester device), which may be an example of a host system 105, and may route data between the external device and one or more memory devices 130. For example, the memory interface circuitry 185 may be configured to receive a command via a first interface having a first set of terminals (e.g., an SCA interface) to configure the memory interface circuitry 185 for a pass-through mode. As part of the pass-through mode, the memory interface circuitry 185 may receive data from the external device via the first interface and output the data to the one or more memory devices 130 via a second interface having a second set of terminals (e.g., an ONFI interface). In some examples, the received data may be associated with a write burst, for which the memory interface circuitry 185 may serially receive multiple (e.g., two or more) portions of the data to write to a buffer of the memory interface circuitry 185. After reaching a threshold quantity of data, the buffer may output the portions of the data to the one or more memory devices 130 via the second interface (e.g., concurrently, in parallel). In such examples, the memory interface circuitry 185 may output the portions of data based on the buffer storing a threshold quantity of data (e.g., in response to or otherwise based on the buffer becoming full).

Configuring the memory interface circuitry 185 to support the pass-through mode may allow the external device to bypass aspects of a memory system controller 115, or some portion thereof, and accordingly may provide an external device direct access to the one or more memory devices 130 in accordance with a simplified interface (e.g., using fewer terminals, in accordance with a reduced command set, in accordance with a reduced clock rate or data rate, in accordance with a reduced capability) relative to other interfaces. Although the example of memory interface circuitry 185 is illustrated outside the memory system controller 115, in some other examples, at least a portion if not all of the memory interface circuitry 185 may be included in a memory system controller 115 (e.g., which may support bypassing another portion of the memory system controller 115). Further, although the example of memory interface circuitry 185 is illustrated as being part of a memory system 110, in some other examples, memory interface circuitry 185 may be implemented in a host system 105, or implemented as part of or in communication with a different system, such as a testing platform, which may combine aspects of a host system 105 and a memory system 110, and which may otherwise provide instructions to and exchange data with one or more memory devices 130.

The system 100 may include any quantity of non-transitory computer readable media that support serial pass-through techniques for memory device interfaces. For example, the host system 105, the memory system 110, or a memory device 130 may include or otherwise may access one or more non-transitory computer readable media storing instructions (e.g., firmware, logic, code) for performing the functions ascribed herein (e.g., to memory interface circuitry 185). For example, such instructions, if executed by a host system 105, by a memory system 110, by a memory device 130, or by otherwise implemented memory interface circuitry 185 (e.g., in a standalone or otherwise integrated implementation) may cause the host system 105, the memory system 110, the memory device 130, or the otherwise implemented memory interface circuitry 185 to perform associated functions as described herein.

FIG. 2 shows an example of memory interface circuitry 185-a that supports serial pass-through techniques for memory device interfaces in accordance with examples as disclosed herein. The memory interface circuitry 185-a may be an example of one or more aspects of memory interface circuitry 185. The memory interface circuitry 185-a may include one or more terminals 225 (e.g., terminals 225-a, 225-b, 225-c), or one or more terminals 235 (e.g., terminals 235-a and 235-b), or both which may support a communicative coupling with an external device (e.g., a host system 105, a testing device). In some cases, the one or more terminals 235 may be different than (e.g., may be exclusive of, may not include) the one or more terminals 225. The memory interface circuitry 185-a also may include one or more terminals 230, including terminals 230-a (e.g., write enable (WE)), 230-b (e.g., address latch enable/command latch enable (ALE/CLE)), 230-c (e.g., chip enable (CE #) [1:0]), 230-d (e.g., DQS/DQ[7:0]), and 230-e (e.g., RE #), which may support a communicative coupling with one or more memory devices 130. In some examples, terminals 230 may be associated with an interface 210 (e.g., an ONFI) between the memory interface circuitry 185-a and such memory devices 130. In various implementations, terminals 225, terminals 230, or terminals 235, or any combination thereof may be accessible by an external device for coupling (e.g., as pins, as pads, at a physical boundary of an associated device). The memory interface circuitry 185-a may be implemented in a memory system 110, or in a host system 105, among other implementations (e.g., as part of a testing platform) for supporting operations between a host and one or more memory devices 130.

In some cases, the terminals 225 and the terminals 235 may be associated with an interface 205, which may be an example of a UFS interface. For example, the terminals 235 may include one or more data terminals 235-a (e.g., DQS/DQ[7:0]), which may be configured to communicate data associated with access operations using the interface 205 between an external device (e.g., a host system 105) and a memory system controller (e.g., a memory system controller 115), and one or more read enable terminals 235-b (e.g., RE #), which may support read operations using the interface 205. The terminals 225 may include one or more clock terminals 225-a (e.g., CA_CLK), which may support communicating a clock signal, one or more command and address (CA) terminals 225-b (e.g., CA[1:0]), which may support receiving commands and addresses associated with access operations using the interface 205, and one or more identifier terminals 225-c (e.g., CE #[3:0]), which may support communicating an indication of one or more memory devices 130 (e.g., a chip-enable signal). In some cases, the indication of the one or more memory devices 130 may be routed to one or more multiplexers 265 (e.g., multiplexers 265-a, 265-b, 265-c, 265-d, 265-e, and 265-f), which may route (e.g., according to an index enabled by the indication) incoming signals to the one or more memory devices 130 associated with the indication. For example, the interface 210, the terminals 230, or both may be repeated (e.g., duplicated) for each index of the multiplexer 265, which may couple multiple memory devices (e.g., at least one memory device associated with each index) with the memory interface circuitry 185-a.

Additionally, or alternatively, the terminals 225 may be associated with an interface 215, which may be an example of an SCA interface. The interface 215 may use the terminals 225 to communicate commands, addresses, data, or any combination thereof associated with accessing memory devices 130 coupled with the memory interface circuitry 185-a. For example, terminals 225-b may be configured to receive commands and addresses associated with access operations, as well as communicate data associated with the access operations. In some examples, the interface 205, the interface 215, or both may communicate in accordance with a double data rate (DDR) signaling. Accordingly, each terminal 225 and each terminal 235 may transmit one bit of data on each rising edge of a clock cycle (e.g., of a clock cycle associated with a clock signal communicated via the clock terminal 225-a) and one bit of data on each falling edge of the clock cycle. Additionally, or alternatively, the interface 205, the interface 215, or both may communicate signaling according to a single data rate (SDR) procedure.

The interface 215, the interface 210, or both may support communicating commands, addresses, and data using multiple (e.g., two) phases of operations. For example, the interface 215 may support a first phase (e.g., a serial command phase) and a second phase (e.g., an independent parallel data bus transfer phase). In some examples, the first phase may be used to preset or arm the second phase by loading the buffer 220-a with a Channel Select, and may be associated with receiving commands and addresses serially via the terminals 225-b. The second phase may be used to program or read one or more memory devices 130, which may involve parallel (e.g., concurrent) signaling via multiple terminals 230. In some cases, an external device (e.g., a host system 105, a tester device) may transmit one or more header cycle types via the terminals 225-b to indicate a type (e.g., a cycle type, a type of command, a type of data) of signaling following the header cycle type. For example, Table 1 illustrates examples of cycle types and associated header cycle types that may be supported by the memory interface circuitry 185-a.

TABLE 1
SCA Header cycle type Decoding

| | Header cycle | | Header cycle | |
|---|---|---|---|---|
| | type Rising Edge | | type Falling Edge | |
| Cycle Type | CA[1] | CA[0] | CA[1] | CA[0] |
| Data Output | 0 | 0 | 0 | 0 |
| Data Input | 0 | 0 | 1 | 0 |
| Address | 0 | 1 | 0 | 0 |
| Controller | 0 | 1 | 1 | 0 |
| Command | 1 | 0 | 0 | 0 |
| NTO | 1 | 0 | 1 | 1 |
| LUN Select | 1 | 1 | 0 | 0 |
| Select Chip Enable | 1 | 1 | 0 | 1 |
| Select Chip Pause | 1 | 1 | 1 | 0 |
| Select Chip | 1 | 1 | 1 | 1 |
| Terminate | | | | |

As described herein, a rising edge and a falling edge may refer to a rising clock signal and a falling clock signal, respectively, which may be driven by an external device via the terminal 225-a. The header cycle types included in Table 1 may be communicated via the terminals 225-b to indicate a data format for signals transmitted after the header cycle type, and may aid in altering the function of the memory interface circuitry 185-a. For example, an external device may enable or disable the “Controller” cycle type by communicating the associated header cycle type from Table 1 via terminals 225-b, followed by signaling a 0 or a 1 bit to disable or enable the “Controller” cycle type, respectively.

Enabling the “Controller” cycle type may enable a mapping to map signaling received subsequent to an “Address” header cycle type to various functions, and may enable the interface decoder 240 to receive subsequent signaling having the “Address” header cycle type. Table 2 may illustrate the mapping, which may map signals received (e.g., information received subsequent to the “Address” header cycle type) to functions for the interface decoder 240.

TABLE 2
Memory Map

| Function | Address |
|---|---|
| Burst Data FIFO (Write) | 4′b0000 |
| Burst Data FIFO Empty/Full | 4′b0001 |
| Burst Data FIFO (Read) | 4′b0010 |
| Start Pattern Write | 4′b0011 |
| Start Pattern Compare | 4′b0100 |
| Pattern Status | 4′b0101 |
| Pattern Faults | 4′b0110 |
| Pattern Seed | 4′b0111 |

By way of example, to support a testing mode of the memory interface circuitry 185-a (e.g., a by-pass testing mode, a SBTM), an external device (e.g., a tester device, a host system 105) may transmit the “Select Chip Enable” header cycle type via the terminals 225-b, and may transmit an indication of one or more memory devices 130 via one or more terminals 225-c. Based on receiving the “Select Chip Enable” header cycle type and the indication of the one or more memory devices 130, the memory interface circuitry 185-a (e.g., using the interface decoder 240) may store the indication in a buffer 220-a (e.g., a burst buffer, a burst FIFO). The indication of the one or more memory devices 130 may be routed to the one or more multiplexers 265 (e.g., via the burst decoder 260), which may support data output by the burst data block 250 to be routed to the indicated one or more memory devices 130. Because the interface 210 (e.g., the ONFI bus) may be shared across the set of memory devices 130, each memory device 130 included in the indication may receive and process signaling (e.g., commands, data) from the external device.

After storing the indication of the one or more memory devices 130 in the buffer 220-a, the external device may transmit a “Controller” header cycle type to enable the mapping, which may configure the interface decoder 240 to process commands (e.g., commands associated with the “Address” header cycle type). For example, to perform a write operation (e.g., a burst data write), the external device may transmit a “Burst Data FIFO (Write)” address type. The external device may subsequently transmit (e.g., using the “Data Output” header cycle type) one or more portions of data via the terminals 225-b, such as one or more codewords (e.g., scrambled data, metadata, low-density parity check (LDPC) parity information, or any combination thereof).

To support translating the data from the bus width used by the interface 215 (e.g., a quantity of terminals 225-b) and the bus width used by the interface 210 (e.g., a quantity of terminals 230-d, which may be greater than the quantity of terminals 225-b), the interface decoder 240 may be configured to store multiple portions of data received serially (e.g., according to the bus width of the interface 215) from the external device to a buffer 220-b (e.g., a data buffer, a burst data FIFO). If the buffer 220-b is full (e.g., based on the interface decoder 240 determining that the buffer 220-b stores a threshold quantity of data), the memory interface circuitry 185-a may transfer data portions stored in the buffer 220-b to the indicated one or more memory devices 130 (e.g., may “flush” the data from the buffer 220-b). For example, the memory interface circuitry 185-a may, via the burst data block 250, output the data portions concurrently (e.g., in parallel), according to the bus width of the interface 210, to the one or more memory devices 130 indicated by the indication stored in the buffer 220-a.

In some examples, after outputting portions of the data, the interface decoder 240 may set a value of a flag associated with the buffer 220-b to indicate that the buffer 220-b is empty. The external device may poll the status of the flag (e.g., using the “Burst Data FIFO Empty/Full” address type) to determine whether the buffer 220-b is empty. Accordingly, if the buffer 220-b is empty, the external device may continue transmitting portions of the data, such that each portion of the data may be stored to the buffer 220-b and output from the buffer 220-b to the one or more memory devices 130.

In some examples, the memory interface circuitry 185-a may support reading of the data by the external device. For example, if the mapping is enabled, the external device may transmit a “Burst Data FIFO (Read)” address type, which may configure the memory interface circuitry 185-a for the read operation, and may subsequently transmit one or more “Data Input” header cycle types.

In response to each “Data Input” cycle type, the interface decoder 240 may retrieve multiple portions of the data from one or more memory devices 130 and store the multiple portions to the buffer 220-b. In some cases, if the buffer 220-b is full (e.g., based on the interface decoder 240 determining that the buffer 220-b stores a threshold quantity of data), the interface decoder 240 may set the value of the flag to indicate that the buffer 220-b is full. The external device may poll the status of the buffer 220-b (e.g., using the “Burst Data FIFO Empty/Full” address type) and, if the buffer 220-b is full, the interface decoder 240 may serially output the portions of data stored at the buffer 220-b to the external device via the Interface 215. In some examples, the memory interface circuitry 185-a may transmit read data via a first terminal 225-b (e.g., a single terminal), and may concurrently transfer a clock signal (e.g., a clock signal generated at the memory interface circuitry 185-a, which may be generated based on the clock signal communicated via the terminal 225-a) via a second terminal 225-b (e.g., a single terminal, different than the first signal) to support outputting the portions of the data.

In some examples, as an alternative to receiving data from the external device, the memory interface circuitry 185-a may support a sequence generator mode (e.g., to test one or more memory devices 130). For example, after enabling the mapping and configuring the memory interface circuitry using the “Controller” cycle type, the external device may transmit the “Start Pattern Write” address type. The external device may then transmit a “Data Output” cycle type initiate a pattern generator. The pattern generator may generate a random sequence (e.g., a PRBS), and store the generated sequence to the indicated one or more memory devices. The interface decoder 240 may support the “Pattern Fault” address type, which may cause the interface decoder 240 to retrieve the generated sequence from the one or more memory devices, and perform an error control operation to identify whether an error occurred in storing or retrieving the sequence. The interface decoder 240 transmit a result of the error control operation (e.g., an indication of whether any errors were detected) to the external device as a response to receiving the Pattern Fault” address type.

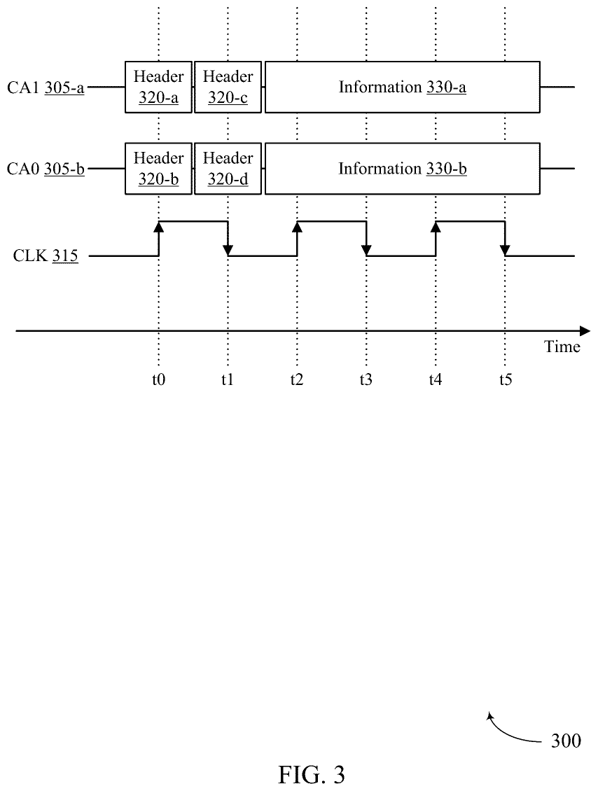

FIG. 3 shows an example of a timing diagram 300 that supports serial pass-through techniques for memory device interfaces in accordance with examples as disclosed herein. Aspects of the timing diagram 300 may be implemented by a system 100 (e.g., memory interface circuitry 185) as described with reference to FIGS. 1 and 2, or various components thereof. The timing diagram 300 illustrates the use of header portions 320, which may indicate a header cycle type of Table 1, and information 330, which may communicate configurations, commands, and data via command/address (CA) channels 305-a and 305-b. For example, the timing diagram 300 illustrates signaling via one or more CA channels (e.g., a CA1 305-a and a CA0 305-b, which may be communicated via respective terminals 225-b, and signaling of a CA clock (e.g., clock signal 315) associated with the CA channels, which may be communicated via a terminal 225-a.

Signaling of the timing diagram 300 may implement an interface (e.g., an interface 215, an SCA interface) that supports serial pass-through techniques for memory device interfaces. The timing diagram 300 may illustrate an example of communication between an external device (e.g., a host system 105, a tester device) coupled with terminals 225 and the one or more memory devices 130 coupled with terminals 230. For example, the timing diagram 300 may include the CA1 305-a and the CA0 305-b channels, which the external device may use to pass information. The external device may transmit one or more header cycle types (e.g., indicated by header portions 320, which may be related to header cycle types of Table 1) via the CA1 305-a, the CA0 305-b, or a combination thereof, followed by information 330 (e.g., information 330-a, information 330-b) related to each header cycle type. These header cycle types may identify commands and may be used by the memory interface circuitry 185 to determine how to decode the information 330 that follows the header cycle type.

The timing diagram 300 illustrates an example of signaling in accordance with a DDR unit interval. For example, the external device may transmit the header portions 320-a and 320-b in accordance with a rising edge of clock signal 315 (e.g., a first unit interval) and may transmit the header portions 320-c and 320-d in accordance with a falling edge (e.g., a second unit interval). In some cases, a single bit of data may be communicated via each CA channel 305 for each rising edge and for each falling edge. For example, CA1 305-a may communicate a single bit for header portion 320-a at time t0, and may communicate a single bit for header portion 320-c at time t1. Similarly, CA0 305-b may transmit a single bit for header portion 320-b at time t0, and may transmit a single bit for header portion 320-d at time t1. Accordingly, the header portions 320 may indicate a header cycle type (e.g., of Table 1), which may include four bits that are mapped to respective header portions 320. The external device may subsequently transmit the associated information 330 via the CA1 305-a, the CA0 305-b, or both, in accordance with the DDR unit interval. In some cases, as part of a read operation, the interface 215 may be implemented to transmit data to the external device via one of the CA1 305-a or the CA0 305-b. For example, memory interface circuitry 185 may transmit retrieved read data via the CA1 305-a, and may transmit a clock signal (e.g., a clock signal generated at the memory interface circuitry 185-a) via the CA0 305-b.

Different types of information and commands may be communicated using the CA channels 305-a and 305-b, and the different types may be associated with different information 330. For example, a cycle type indicated by header portions 320 may be communicated using the CA channels to enable the memory interface to decode the information 330 that follows the header portions 320. For example, memory interface circuitry 185 (e.g., an interface decoder 240) may decode a 4-bit header cycle type (e.g., as a combined decoding of four header portions 320) and may identify a cycle type from the decoded header cycle type to decode (e.g., interpret) the information 330 that follows the header portions 320 (e.g., information 330-a and 330-b). In some examples, different header cycle types may be used to indicate information about the clock cycle in relation to the memory system and buffer. For example, the external device may send header portions 320 associated with a “Data Output” cycle type or a “Data Input” cycle type from Table 1 to indicate to the memory interface circuitry 185 that a data transfer may occur. Similarly, the external device may send an “Address” header cycle type or a “Command” header cycle type from Table 1, which may indicate information regarding the CA bus.

As described herein, an external device may send the “Select Chip Enable” header cycle type from Table 1 to activate (e.g., enable) chip select lines and enable a data transfer, and the external device may send the “Select Chip Pause” header cycle type from Table 1 to similarly deactivate chip select lines and pause the data transfer. Additionally, the external device may send the “Select Chip Terminate” header cycle type from Table 1 to trigger the erasure of the channel select indicator from the buffer 220-a, and terminate the data transfer.

Additionally, the external device may send the “Controller” header cycle type to enable the mapping, which may configure the memory interface circuitry 185 (e.g., interface decoder 240) to decode subsequent commands having the “Address” header cycle type. For example, the memory interface circuitry 185 may determine to perform various functions in response to receiving an “Address” header cycle type, and the particular function may be determined by the subsequent information 330, in accordance with Table 2.

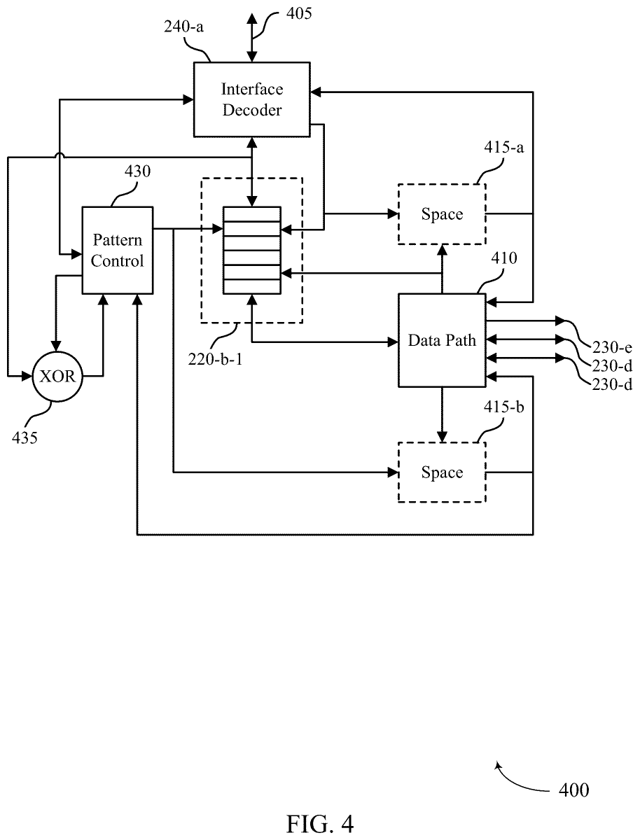

FIG. 4 shows an example of a memory interface architecture 400 that supports serial pass-through techniques for memory device interfaces in accordance with examples as disclosed herein. The memory interface architecture 400 may illustrate an example of implementing aspects of (e.g., may be included in) memory interface circuitry 185. For example, the memory interface architecture 400 may be coupled with an external device (e.g., a host system 105, a tester device) via an interface, such as an interface 215, via a bus 405 (e.g., via terminals 225), and may be coupled with one or more memory devices 130 via a read enable terminal 230-e, and one or more terminals 230-d. The memory interface architecture 400 may include an interface decoder 240-a, which may receive signaling (e.g., commands, addresses, data) via the bus 405 and may output data to a buffer 220-b-1. The buffer 220-b-1 may also receive data from a pattern control 430 (e.g., pattern generator logic), and may send and receive data to and from the one or more memory devices 130 through a data path 410 (e.g., via an interface 210). The pattern control 430 may couple with a pattern compare circuit 435, which may be an example of an exclusive or (XOR) comparator. The data path 410 may optionally be coupled with one or more space circuits 415 (e.g., space circuit 415-a and space circuit 415-b), and may communicate data via the read enable terminal 230-e and the terminals 230-d.

The memory interface architecture 400 may support generation of a sequence (e.g., a random sequence, a PRBS), which may be used to evaluate memory devices 130. For example, the memory interface architecture 400 may receive a first command via the bus 405, such as a “Select Chip Enable” header cycle type. As part of the first command, the memory interface architecture 400 may write an indication of one or more memory devices 130 to another buffer (e.g., a buffer 220-a).

In some instances, the external device may use the header cycle types and address values of Table 1 and Table 2 as commands to generate and transmit the sequence from the memory interface architecture 400 to the one or more memory devices 130 coupled with the memory interface architecture 400. For example, the external device may transmit the “Controller” header cycle type, and a “1” bit to enable the memory mapping described illustrated in Table 2. Subsequently, the external device may transmit an “Address” header cycle type from Table 1, and the “Start Pattern Write” address from Table 2, to configure the interface decoder 240-a to generate the sequence based on the indication stored in the first buffer.

The external device may transmit a “Data Output” header cycle type from Table 1 with a command to enable the pattern control 430 to initiate generating the sequence. In some examples, the pattern control 430 may use a seed value in generating the sequence (e.g., as a seed of a random number generator). The external device may transmit a command, such as the “Pattern Seed” address type, to transmit and set the seed of the pattern control 430. In other cases, the pattern control 430 may generate a seed value for the sequence (e.g., autonomously).

In response to the “Data Output” header cycle type, the pattern control 430 may generate the sequence, and may write one or more portions of the sequence to the buffer 220-b-1. Based on determining that buffer 220-b-1 is full, the memory interface architecture 400 may output the portions of the sequence from the buffer 220-b-1 to the indicated one or more memory devices 130. In some cases, the space circuit 415-b may track the amount of data written to the buffer 220-b-1, and may notify the memory interface architecture 400 if the amount of data written to the buffer 220-b-1 satisfies a threshold (e.g., if the buffer 220-b-1 is full). Subsequently, the pattern control 430 may write additional portions (e.g., a second portion, a third portion, and so on) of the sequence to the buffer 220-b-1, and the buffer 220-b-1 may output the additional portions to the one or more indicated memory devices 130.

In some instances, the external device may transmit a command to poll a pattern status register to determine whether the sequence has been transferred from the pattern control 430 and stored in the one or more memory devices 130 coupled with the memory interface architecture 400. For example, the external device may transmit the “Address” header cycle type from Table 1, and the “Pattern Status” address from Table 2, to poll the pattern status register of the memory interface architecture 400. In response, the memory interface architecture 400 may transmit an indication to the external device of whether the sequence was stored in the one or more memory devices 130 (e.g., whether the operation of generating and storing the sequence is complete). In some cases, the pattern control 430 may use the buffer 220-b-1.

Header cycle types and addresses from Table 1 and Table 2 may similarly be used to determine whether the sequence was correctly stored to the one or more memory devices 130. For example, the external device may transmit the “Address” header cycle type from Table 1 and the “Start Pattern Compare” address form Table 2, and may subsequently transmit the “Data Output” header cycle type from Table 1 to enable the pattern control 430 to begin a sequence read operation. In some examples, the external device may poll the pattern status register to determine when the sequence read operation is complete. The pattern control 430 may use the buffer 220-b-1 to read the sequence from the one or more memory devices 130. For example, the space circuit 415-a may track an amount of data (e.g., the sequence) that is read from the one or more memory devices 130 to the buffer 220-b-1 The space circuit 415-a may alert the memory interface architecture 400 if the amount of data satisfies a threshold, which may notify the buffer 220-b-1 to transfer the read data to the pattern control 430.

In some examples, the memory interface architecture 400 may perform an error detection procedure to compare the retrieved sequence with the originally generated sequence. For example, based on (e.g., in response to) retrieving the sequence, the memory interface architecture 400 may generate a second sequence using the same seed used to generate the initial sequence. The memory interface architecture 400 may compare the second sequence with the retrieved sequence (e.g., using the pattern compare circuit 435), and may determine an error rate (e.g., a percentage of bits of the retrieved sequence which do not match the second sequence), a quantity of errors (e.g., a quantity of bits of the retrieved sequence which do not match the second sequence), or both. The external device may transmit a command, such as the “Pattern Faults” address, to retrieve the error rate, the quantity of errors, or both. In some examples, the memory interface architecture 400 may provide a result of such comparisons or determinations (e.g., an indication of a presence or quantity of errors, a pass/fail indication) to the external device via the bus 405.

Thus, in accordance with these and other examples, memory interface circuitry 185 may be configured to support a pass-through mode, which may allow an external device to bypass aspects of a memory system controller 115 and, in some examples, may provide an external device direct access to one or more memory devices 130 in accordance with a simplified interface (e.g., using fewer terminals, in accordance with a reduced command set, in accordance with a reduced clock rate or data rate, in accordance with a reduced capability) relative to other interfaces. Such techniques may support improved techniques for evaluation of memory devices 130 (e.g., simplified techniques, techniques that may be supported even in the event of a failed memory system controller 115), or may provide direct access to memory devices 130, such as for re-use implementations that may implement a lower-performance interface, or which may bypass aspects of a memory system controller 115 (e.g., in the event of a failure of a memory system controller 115, to reuse memory devices 130 that are still functional). Accordingly, implementing the techniques described herein may support techniques for increased connectivity in electronic systems by allowing for increased flexibility of types of testing devices, which may increase adaptability and use-cases of electronic systems, among other benefits.

FIG. 5 shows a block diagram 500 of a memory interface 520 that supports serial pass-through techniques for memory device interfaces in accordance with examples as disclosed herein. The memory interface 520 may be an example of aspects of a memory interface (e.g., memory interface circuitry) as described with reference to FIGS. 1 through 4. The memory interface 520, or various components thereof, may be an example of means for performing various aspects of serial pass-through techniques for memory device interfaces as described herein. For example, the memory interface 520 may include a reception component 525, a buffer write component 530, a buffer output component 535, a memory device indication component 540, a pattern generation component 545, a transmission component 550, an error control component 555, a buffer control component 560, or any combination thereof. Each of these components may communicate, directly or indirectly, with one another (e.g., via one or more buses).

In some examples, the memory interface 520 may be configured to support one or more first implementations of serial pass-through techniques for memory device interfaces as disclosed herein. For example, the reception component 525 may be configured as or otherwise support a means for receiving, at memory interface circuitry that is coupled with one or more memory devices, a command (e.g., a command to initiate a “Burst Data FIFO” mode) via a plurality of first terminals to configure the memory interface circuitry to receive data associated with a write burst, the plurality of first terminals associated with a first quantity of terminals. The buffer write component 530 may be configured as or otherwise support a means for writing a first portion of the data to a buffer of the memory interface circuitry based at least in part on receiving the first portion of the data via the plurality of first terminals during a first duration. In some examples, the buffer write component 530 may be configured as or otherwise support a means for writing a second portion of the data to the buffer of the memory interface circuitry based at least in part on receiving the second portion of the data via the plurality of first terminals during a second duration that is after the first duration. The buffer output component 535 may be configured as or otherwise support a means for outputting, from the buffer via a plurality of second terminals, the first portion of the data and the second portion of the data to one or more memory devices based at least in part on determining that an amount of data written to the buffer satisfies a threshold, the plurality of second terminals associated with a second quantity of terminals that is greater than the first quantity of terminals. In some examples, the first portion of the data and the second portion of the data may be output concurrently via the plurality of second terminals.

In some examples, the reception component 525 may be configured as or otherwise support a means for receiving, at the memory interface circuitry, a second command (e.g., a command to enter a “Select Chip Enable” cycle type) via the plurality of first terminals to write an indication of the one or more memory devices. In some examples, the memory device indication component 540 may be configured as or otherwise support a means for writing the indication of the one or more memory devices to the memory interface circuitry based at least in part on receiving the second command, and transferring the first portion of the data and the second portion of the data may be based at least in part on writing the indication.

In some examples, the reception component 525 may be configured as or otherwise support a means for receiving, at the memory interface circuitry, the indication of the one or more memory devices via one or more third terminals exclusive of the plurality of first terminals, and writing the indication of the one or more memory devices may be based at least in part on receiving the indication of the one or more memory devices.

In some examples, the reception component 525 may be configured as or otherwise support a means for receiving, at the memory interface circuitry, a second command (e.g., a command to enter a “Controller” cycle type) via the plurality of first terminals to enable a mapping associated with a header cycle type of the command and one or more functions of the memory interface circuitry, and receiving the command may be based at least in part on enabling the mapping.

In some examples, the reception component 525 may be configured as or otherwise support a means for receiving, at the memory interface circuitry via the plurality of first terminals after the second duration, a second command (e.g., a “Burst Data FIFO Empty/Full” command) to determine whether the buffer is empty. In some examples, the transmission component 550 may be configured as or otherwise support a means for outputting an indication that the buffer is empty via the plurality of first terminals based at least in part on transferring the first portion of the data and the second portion of the data and in response to receiving the second command.

In some examples, the buffer control component 560 may be configured as or otherwise support a means for determining that the buffer is empty based at least in part on outputting the first portion of the data and the second portion of the data. In some examples, the buffer control component 560 may be configured as or otherwise support a means for setting a value of a flag of the memory interface circuitry based at least in part on the determining, where the indication that the buffer is empty includes the value of the flag. In some examples, a header cycle type of the command and a header cycle type of the second command may be associated with a same value.

In some examples, the reception component 525 may be configured as or otherwise support a means for receiving, at the memory interface circuitry via the plurality of first terminals, a second command (e.g., a “Burst Data FIFO (Read)” command) to read the data from the one or more memory devices. In some examples, the buffer write component 530 may be configured as or otherwise support a means for receiving, via the plurality of second terminals based at least in part on receiving the second command, the first portion of the data and the second portion of the data from the one or more memory devices. In some examples, the transmission component 550 may be configured as or otherwise support a means for outputting, during a third duration, the first portion of the data via a subset of the plurality of first terminals. In some examples, the transmission component 550 may be configured as or otherwise support a means for outputting, during a fourth duration after the third duration, the second portion of the data via the subset of the plurality of first terminals.

In some examples, the transmission component 550 may be configured as or otherwise support a means for outputting, during the third duration and during the fourth duration, a clock signal via a second subset of the plurality of first terminals that is exclusive of the second subset.

In some examples, to support outputting the first portion of the data and the second portion of the data, the buffer output component 535 may be configured as or otherwise support a means for outputting the first portion of the data and the second portion of the data from the buffer to a respective controller of each of the one or more memory devices.

In some examples, to support outputting the first portion of the data and the second portion of the data, the buffer output component 535 may be configured as or otherwise support a means for outputting the first portion of the data and the second portion of the data from the buffer to a first memory device of the one or more memory devices and to a second memory device of the one or more memory devices.

In some examples, a bus of the memory interface circuitry includes the plurality of first terminals, one or more third terminals, and a fourth terminal. In some examples, the plurality of first terminals may be associated with communicating commands, addresses, and data, the one or more third terminals may be associated with communicating an indication of the one or more memory devices, and the fourth terminal may be associated with communicating a clock signal.

In some examples, the plurality of first terminals may be associated with an SCA interface and the plurality of second terminals is associated with an ONFI.

Additionally, or alternatively, the memory interface 520 may be configured to support one or more second implementations of serial pass-through techniques for memory device interfaces as disclosed herein. For example, the reception component 525 may be configured as or otherwise support a means for receiving, at memory interface circuitry that is coupled with one or more memory devices, a first command (e.g., a “Select Chip Enable” command) via a plurality of first terminals to write an indication of the one or more memory devices, the plurality of first terminals associated with a first quantity of terminals. The memory device indication component 540 may be configured as or otherwise support a means for writing the indication of the one or more memory devices to the memory interface circuitry based at least in part on receiving the first command. The reception component 525 may be configured as or otherwise support a means for receiving, at the memory interface circuitry, a second command (e.g., a “Start Pattern Write” command) via the plurality of first terminals to configure the memory interface circuitry to generate a data sequence based at least in part on writing the indication. The pattern generation component 545 may be configured as or otherwise support a means for writing a first portion of the data sequence to a buffer of the memory interface circuitry based at least in part on generating the data sequence. The buffer output component 535 may be configured as or otherwise support a means for outputting, from the buffer via a plurality of second terminals, the first portion of the data sequence to the one or more memory devices based at least in part on determining that an amount of data written to the buffer satisfies a threshold. The pattern generation component 545 may be configured as or otherwise support a means for writing a second portion of the data sequence to the buffer based at least in part on generating the data sequence and transferring the first portion.

In some examples, the reception component 525 may be configured as or otherwise support a means for receiving, at the memory interface circuitry via the plurality of first terminals, a third command (e.g., a “Controller” command) to enable a mapping associated with a header cycle type of the second command and one or more functions of the memory interface circuitry, and receiving the second command may be based at least in part on enabling the mapping.

In some examples, the reception component 525 may be configured as or otherwise support a means for receiving, at the memory interface circuitry via the plurality of first terminals, a third command (e.g., a “Pattern Status” command) to determine whether the data sequence was stored to the one or more memory devices. In some examples, the transmission component 550 may be configured as or otherwise support a means for outputting, from the memory interface circuitry via the plurality of first terminals, an indication that the data sequence was stored in response to receiving the third command.

In some examples, the reception component 525 may be configured as or otherwise support a means for receiving, at the memory interface circuitry via the plurality of first terminals, a third command (e.g., a “Start Pattern Compare” command) to perform an error evaluation of at least one of the one or more memory devices. In some examples, the error control component 555 may be configured as or otherwise support a means for perform the error evaluation of the at least one of the one or more memory devices based at least in part on reading the data sequence from the at least one of the one or more memory devices. In some examples, the transmission component 550 may be configured as or otherwise support a means for outputting a response to the third command based at least in part on performing the error evaluation.

In some examples, to support performing the error evaluation, the pattern generation component 545 may be configured as or otherwise support a means for generating a second data sequence based at least in part on a seed value. In some examples, to support performing the error evaluation, the error control component 555 may be configured as or otherwise support a means for comparing the second data sequence with the data sequence read from the at least one of the one or more memory devices to determine an error rate, and generating the data sequence may be based at least in part on the seed value.

In some examples, the reception component 525 may be configured as or otherwise support a means for receiving, via the plurality of first terminals, a third command to set a seed value, and generating the data sequence may be based at least in part on the seed value.

In some examples, the data sequence may include a PRBS.

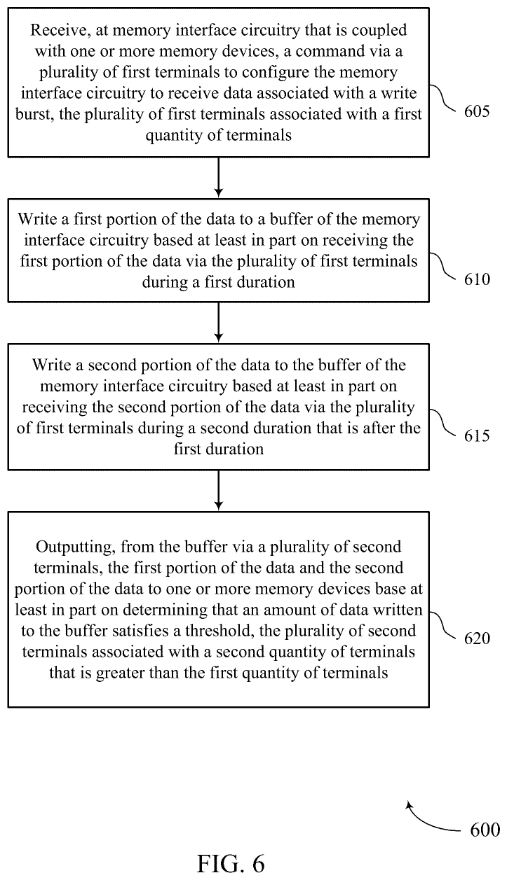

FIG. 6 shows a flowchart illustrating a method 600 that supports serial pass-through techniques for memory device interfaces in accordance with examples as disclosed herein. The operations of method 600 may be implemented by a memory interface or its components as described herein. For example, the operations of method 600 may be performed by a memory interface (e.g., memory interface circuitry operable to couple with one or more memory devices, a controller coupled with the memory interface and configured to support one or more of the operations of method 600) as described with reference to FIGS. 1 through 5. In some examples, a memory interface may execute a set of instructions to control the functional elements of the device to perform the described functions. Additionally, or alternatively, the memory interface may perform aspects of the described functions using special-purpose hardware.

At 605, the method may include receiving, at memory interface circuitry that is coupled with one or more memory devices, a command via a plurality of first terminals to configure the memory interface circuitry to receive data associated with a write burst, the plurality of first terminals associated with a first quantity of terminals. The operations of 605 may be performed in accordance with examples as disclosed herein. In some examples, aspects of the operations of 605 may be performed by a reception component 525 as described with reference to FIG. 5.

At 610, the method may include writing a first portion of the data to a buffer of the memory interface circuitry based at least in part on receiving the first portion of the data via the plurality of first terminals during a first duration. The operations of 610 may be performed in accordance with examples as disclosed herein. In some examples, aspects of the operations of 610 may be performed by a buffer write component 530 as described with reference to FIG. 5.

At 615, the method may include writing a second portion of the data to the buffer of the memory interface circuitry based at least in part on receiving the second portion of the data via the plurality of first terminals during a second duration that is after the first duration. The operations of 615 may be performed in accordance with examples as disclosed herein. In some examples, aspects of the operations of 615 may be performed by a buffer write component 530 as described with reference to FIG. 5.

At 620, the method may include outputting, from the buffer via a plurality of second terminals, the first portion of the data and the second portion of the data to one or more memory devices based at least in part on determining that an amount of data written to the buffer satisfies a threshold, the plurality of second terminals associated with a second quantity of terminals that is greater than the first quantity of terminals. The operations of 620 may be performed in accordance with examples as disclosed herein. In some examples, aspects of the operations of 620 may be performed by a buffer output component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, at memory interface circuitry that is coupled with one or more memory devices, a command via a plurality of first terminals to configure the memory interface circuitry to receive data associated with a write burst, the plurality of first terminals associated with a first quantity of terminals; writing a first portion of the data to a buffer of the memory interface circuitry based at least in part on receiving the first portion of the data via the plurality of first terminals during a first duration; writing a second portion of the data to the buffer of the memory interface circuitry based at least in part on receiving the second portion of the data via the plurality of first terminals during a second duration that is after the first duration; and outputting, from the buffer via a plurality of second terminals, the first portion of the data and the second portion of the data to one or more memory devices based at least in part on determining that an amount of data written to the buffer satisfies a threshold, the plurality of second terminals associated with a second quantity of terminals that is greater than the first quantity of terminals.

Aspect 2: The method, apparatus, or non-transitory computer-readable medium of aspect 1, further including operations, features, circuitry, logic, means, or instructions, or any combination thereof for receiving, at the memory interface circuitry, a second command via the plurality of first terminals to write an indication of the one or more memory devices and writing the indication of the one or more memory devices to the memory interface circuitry based at least in part on receiving the second command, where transferring the first portion of the data and the second portion of the data is based at least in part on writing the indication.

Aspect 3: The method, apparatus, or non-transitory computer-readable medium of aspect 2, further including operations, features, circuitry, logic, means, or instructions, or any combination thereof for receiving, at the memory interface circuitry, the indication of the one or more memory devices via one or more third terminals exclusive of the plurality of first terminals, where writing the indication of the one or more memory devices is based at least in part on receiving the indication of the one or more memory devices.

Aspect 4: The method, apparatus, or non-transitory computer-readable medium of any of aspects 1 through 3, further including operations, features, circuitry, logic, means, or instructions, or any combination thereof for receiving, at the memory interface circuitry, a second command via the plurality of first terminals to enable a mapping associated with a header cycle type of the command and one or more functions of the memory interface circuitry, where receiving the command is based at least in part on enabling the mapping.

Aspect 5: The method, apparatus, or non-transitory computer-readable medium of any of aspects 1 through 4, further including operations, features, circuitry, logic, means, or instructions, or any combination thereof for receiving, at the memory interface circuitry via the plurality of first terminals after the second duration, a second command to determine whether the buffer is empty and outputting an indication that the buffer is empty via the plurality of first terminals based at least in part on transferring the first portion of the data and the second portion of the data and in response to receiving the second command.

Aspect 6: The method, apparatus, or non-transitory computer-readable medium of aspect 5, further including operations, features, circuitry, logic, means, or instructions, or any combination thereof for determining that the buffer is empty based at least in part on outputting the first portion of the data and the second portion of the data and setting a value of a flag of the memory interface circuitry based at least in part on the determining, where the indication that the buffer is empty includes the value of the flag.

Aspect 7: The method, apparatus, or non-transitory computer-readable medium of any of aspects 5 through 6, where a header cycle type of the command and a header cycle type of the second command are associated with a same value.

Aspect 8: The method, apparatus, or non-transitory computer-readable medium of any of aspects 1 through 7, where the first portion of the data and the second portion of the data are output concurrently via the plurality of second terminals.

Aspect 9: The method, apparatus, or non-transitory computer-readable medium of any of aspects 1 through 8, further including operations, features, circuitry, logic, means, or instructions, or any combination thereof for receiving, at the memory interface circuitry via the plurality of first terminals, a second command to read the data from the one or more memory devices; receiving, via the plurality of second terminals based at least in part on receiving the second command, the first portion of the data and the second portion of the data from the one or more memory devices; outputting, during a third duration, the first portion of the data via a subset of the plurality of first terminals; and outputting, during a fourth duration after the third duration, the second portion of the data via the subset of the plurality of first terminals.

Aspect 10: The method, apparatus, or non-transitory computer-readable medium of aspect 9, further including operations, features, circuitry, logic, means, or instructions, or any combination thereof for outputting, during the third duration and during the fourth duration, a clock signal via a second subset of the plurality of first terminals that is exclusive of the second subset.

Aspect 11: The method, apparatus, or non-transitory computer-readable medium of any of aspects 1 through 10, where outputting the first portion of the data and the second portion of the data includes operations, features, circuitry, logic, means, or instructions, or any combination thereof for outputting the first portion of the data and the second portion of the data from the buffer to a respective controller of each of the one or more memory devices.

Aspect 12: The method, apparatus, or non-transitory computer-readable medium of any of aspects 1 through 11, where outputting the first portion of the data and the second portion of the data includes operations, features, circuitry, logic, means, or instructions, or any combination thereof for outputting the first portion of the data and the second portion of the data from the buffer to a first memory device of the one or more memory devices and to a second memory device of the one or more memory devices.

Aspect 13: The method, apparatus, or non-transitory computer-readable medium of any of aspects 1 through 12, where a bus of the memory interface circuitry includes the plurality of first terminals, one or more third terminals, and a fourth terminal and the plurality of first terminals are associated with communicating commands, addresses, and data, the one or more third terminals are associated with communicating an indication of the one or more memory devices, and the fourth terminal is associated with communicating a clock signal.

Aspect 14: The method, apparatus, or non-transitory computer-readable medium of any of aspects 1 through 13, where the plurality of first terminals is associated with an SCA interface and the plurality of second terminals is associated with ONFI.

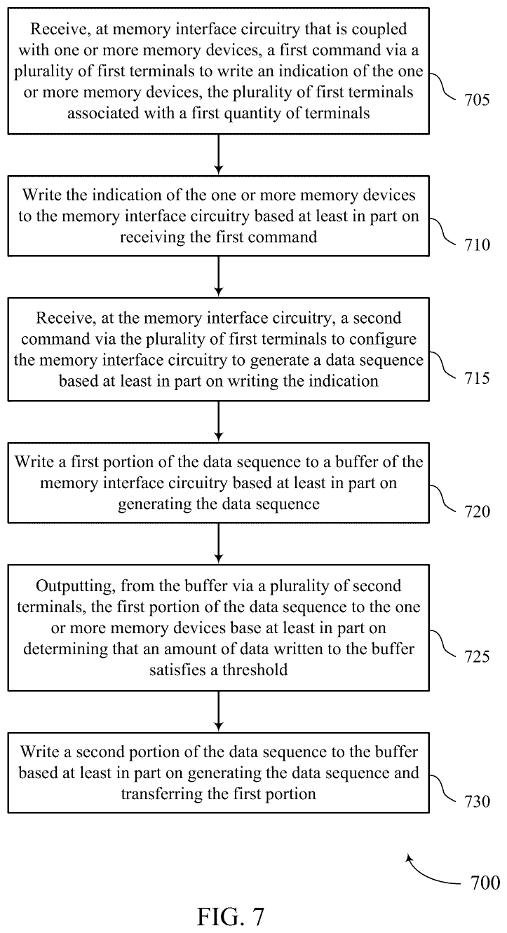

FIG. 7 shows a flowchart illustrating a method 700 that supports serial pass-through techniques for memory device interfaces in accordance with examples as disclosed herein. The operations of method 700 may be implemented by a memory interface (e.g., memory interface circuitry operable to couple with one or more memory devices, a controller coupled with the memory interface and configured to support one or more of the operations of method 700) or its components as described herein. For example, the operations of method 700 may be performed by a memory interface as described with reference to FIGS. 1 through 5. In some examples, a memory interface may execute a set of instructions to control the functional elements of the device to perform the described functions. Additionally, or alternatively, the memory interface may perform aspects of the described functions using special-purpose hardware.

At 705, the method may include receiving, at memory interface circuitry that is coupled with one or more memory devices, a first command via a plurality of first terminals to write an indication of the one or more memory devices, the plurality of first terminals associated with a first quantity of terminals. The operations of 705 may be performed in accordance with examples as disclosed herein. In some examples, aspects of the operations of 705 may be performed by a reception component 525 as described with reference to FIG. 5.

At 710, the method may include writing the indication of the one or more memory devices to the memory interface circuitry based at least in part on receiving the first command. The operations of 710 may be performed in accordance with examples as disclosed herein. In some examples, aspects of the operations of 710 may be performed by a memory device indication component 540 as described with reference to FIG. 5.

At 715, the method may include receiving, at the memory interface circuitry, a second command via the plurality of first terminals to configure the memory interface circuitry to generate a data sequence based at least in part on writing the indication. The operations of 715 may be performed in accordance with examples as disclosed herein. In some examples, aspects of the operations of 715 may be performed by a reception component 525 as described with reference to FIG. 5.

At 720, the method may include writing a first portion of the data sequence to a buffer of the memory interface circuitry based at least in part on generating the data sequence. The operations of 720 may be performed in accordance with examples as disclosed herein. In some examples, aspects of the operations of 720 may be performed by a pattern generation component 545 as described with reference to FIG. 5.

At 725, the method may include outputting, from the buffer via a plurality of second terminals, the first portion of the data sequence to the one or more memory devices based at least in part on determining that an amount of data written to the buffer satisfies a threshold. The operations of 725 may be performed in accordance with examples as disclosed herein. In some examples, aspects of the operations of 725 may be performed by a buffer output component 535 as described with reference to FIG. 5.

At 730, the method may include writing a second portion of the data sequence to the buffer based at least in part on generating the data sequence and transferring the first portion. The operations of 730 may be performed in accordance with examples as disclosed herein. In some examples, aspects of the operations of 730 may be performed by a pattern generation component 545 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 15: A method, apparatus, or non-transitory computer-readable medium including operations, features, circuitry, logic, means, or instructions, or any combination thereof for receiving, at memory interface circuitry that is coupled with one or more memory devices, a first command via a plurality of first terminals to write an indication of the one or more memory devices, the plurality of first terminals associated with a first quantity of terminals; writing the indication of the one or more memory devices to the memory interface circuitry based at least in part on receiving the first command; receiving, at the memory interface circuitry, a second command via the plurality of first terminals to configure the memory interface circuitry to generate a data sequence based at least in part on writing the indication; writing a first portion of the data sequence to a buffer of the memory interface circuitry based at least in part on generating the data sequence; outputting, from the buffer via a plurality of second terminals, the first portion of the data sequence to the one or more memory devices based at least in part on determining that an amount of data written to the buffer satisfies a threshold; and writing a second portion of the data sequence to the buffer based at least in part on generating the data sequence and transferring the first portion.

Aspect 16: The method, apparatus, or non-transitory computer-readable medium of aspect 15, further including operations, features, circuitry, logic, means, or instructions, or any combination thereof for receiving, at the memory interface circuitry via the plurality of first terminals, a third command to enable a mapping associated with a header cycle type of the second command and one or more functions of the memory interface circuitry, where receiving the second command is based at least in part on enabling the mapping.

Aspect 17: The method, apparatus, or non-transitory computer-readable medium of any of aspects 15 through 16, further including operations, features, circuitry, logic, means, or instructions, or any combination thereof for receiving, at the memory interface circuitry via the plurality of first terminals, a third command to determine whether the data sequence was stored to the one or more memory devices and outputting, from the memory interface circuitry via the plurality of first terminals, an indication that the data sequence was stored in response to receiving the third command.

Aspect 18: The method, apparatus, or non-transitory computer-readable medium of any of aspects 15 through 17, further including operations, features, circuitry, logic, means, or instructions, or any combination thereof for receiving, at the memory interface circuitry via the plurality of first terminals, a third command to perform an error evaluation of at least one of the one or more memory devices; perform the error evaluation of the at least one of the one or more memory devices based at least in part on reading the data sequence from the at least one of the one or more memory devices; and outputting a response to the third command based at least in part on performing the error evaluation.

Aspect 19: The method, apparatus, or non-transitory computer-readable medium of aspect 18, where performing the error evaluation includes operations, features, circuitry, logic, means, or instructions, or any combination thereof for generating a second data sequence based at least in part on a seed value and comparing the second data sequence with the data sequence read from the at least one of the one or more memory devices to determine an error rate, where generating the data sequence is based at least in part on the seed value.

Aspect 20: The method, apparatus, or non-transitory computer-readable medium of any of aspects 15 through 19, further including operations, features, circuitry, logic, means, or instructions, or any combination thereof for receiving, via the plurality of first terminals, a third command to set a seed value, where generating the data sequence is based at least in part on the seed value.

Aspect 21: The method, apparatus, or non-transitory computer-readable medium of any of aspects 15 through 20, where the data sequence includes a pseudo-random binary sequence (PRBS).

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 22: A system, including: one or more memory devices; a plurality of first terminals; a plurality of second terminals; a memory system controller coupled with the one or more memory devices and with the plurality of second terminals; and memory interface circuitry coupled with the one or more memory devices and with the plurality of first terminals, the memory interface circuitry comprising a buffer and configured to: receive, via the plurality of first terminals, a command to configure the memory interface circuitry to receive data associated with a write burst; receive, via the plurality of first terminals during a first duration, a first portion of the data to write to the buffer; receive, via the plurality of first terminals during a second duration after the first duration and, a second portion of the data to write to the buffer; and output the first portion of the data and the second portion of the data from the buffer concurrently to at least one of the one or more memory devices based at least in part on determining that an amount of data written to the buffer satisfies a threshold.

Aspect 23: The system of aspect 22, where the memory interface circuitry is further configured to: receive, via the plurality of first terminals, a second command to generate a data sequence; generate the data sequence for writing to the buffer based at least in part on the second command; and output the data sequence from the buffer to at least one of the one or more memory devices.

Aspect 24: The system of any of aspects 22 through 23, where the memory interface circuitry is configured to bypass the memory system controller for communicating with the one or more memory devices.

Aspect 25: The system of any of aspects 22 through 24, where a quantity of the plurality of second terminals is greater than a quantity of the plurality of first terminals.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components via a conductive path to a closed-circuit relationship between components in which signals are capable of being communicated between components via the conductive path. If a component, such as a controller, couples other components together, the component initiates a change that allows signals to flow between the other components via a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted via, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
memory interface circuitry operable to couple with one or more memory devices; and
processing circuitry coupled with the memory interface circuitry and configured to cause the memory system to:
receive, at the memory interface circuitry, a command via a plurality of first terminals to configure the memory interface circuitry to receive data associated with a write burst, the plurality of first terminals associated with a first quantity of terminals;
write a first portion of the data to a buffer of the memory interface circuitry based at least in part on receiving the first portion of the data via the plurality of first terminals during a first duration;
write a second portion of the data to the buffer of the memory interface circuitry based at least in part on receiving the second portion of the data via the plurality of first terminals during a second duration that is after the first duration; and
output, from the buffer via a plurality of second terminals, the first portion of the data and the second portion of the data to the one or more memory devices based at least in part on determining that an amount of data written to the buffer satisfies a threshold, the plurality of second terminals associated with a second quantity of terminals that is greater than the first quantity of terminals.

2. The memory system of claim 1, wherein the processing circuitry is further configured to cause the memory system to:
receive, at the memory interface circuitry, a second command via the plurality of first terminals to write an indication of the one or more memory devices; and
write the indication of the one or more memory devices to the memory interface circuitry based at least in part on receiving the second command, wherein transferring the first portion of the data and the second portion of the data is based at least in part on writing the indication.

3. The memory system of claim 2, wherein the processing circuitry is further configured to cause the memory system to:
receive, at the memory interface circuitry, the indication of the one or more memory devices via one or more third terminals exclusive of the plurality of first terminals, wherein writing the indication of the one or more memory devices is based at least in part on receiving the indication of the one or more memory devices.

4. The memory system of claim 1, wherein the processing circuitry is further configured to cause the memory system to:
receive, at the memory interface circuitry, a second command via the plurality of first terminals to enable a mapping associated with a header cycle type of the command and one or more functions of the memory interface circuitry, wherein receiving the command is based at least in part on enabling the mapping.

5. The memory system of claim 1, wherein the processing circuitry is further configured to cause the memory system to:
receive, at the memory interface circuitry via the plurality of first terminals after the second duration, a second command to determine whether the buffer is empty; and
output an indication that the buffer is empty via the plurality of first terminals based at least in part on transferring the first portion of the data and the second portion of the data and in response to receiving the second command.

6. The memory system of claim 5, wherein the processing circuitry is further configured to cause the memory system to:
determine that the buffer is empty based at least in part on outputting the first portion of the data and the second portion of the data; and
set a value of a flag of the memory interface circuitry based at least in part on the determining, wherein the indication that the buffer is empty comprises the value of the flag.

7. The memory system of claim 1, wherein the first portion of the data and the second portion of the data are output concurrently via the plurality of second terminals.

8. The memory system of claim 1, wherein the processing circuitry is further configured to cause the memory system to:
receive, at the memory interface circuitry via the plurality of first terminals, a second command to read the data from the one or more memory devices;
receive, via the plurality of second terminals based at least in part on receiving the second command, the first portion of the data and the second portion of the data from the one or more memory devices;
output, during a third duration, the first portion of the data via a subset of the plurality of first terminals; and
output, during a fourth duration after the third duration, the second portion of the data via the subset of the plurality of first terminals.

9. The memory system of claim 8, wherein the processing circuitry is further configured to cause the memory system to:
output, during the third duration and during the fourth duration, a clock signal via a second subset of the plurality of first terminals that are exclusive of the second subset.

10. The memory system of claim 1, wherein outputting the first portion of the data and the second portion of the data is configured to cause the memory system to:
output the first portion of the data and the second portion of the data from the buffer to a respective controller of each of the one or more memory devices.

11. The memory system of claim 1, wherein outputting the first portion of the data and the second portion of the data is configured to cause the memory system to:
output the first portion of the data and the second portion of the data from the buffer to a first memory device of the one or more memory devices and to a second memory device of the one or more memory devices.

12. The memory system of claim 1, wherein a bus of the memory interface circuitry comprises the plurality of first terminals, one or more third terminals, and a fourth terminal, and the plurality of first terminals are associated with communicating commands, addresses, and data, the one or more third terminals are associated with communicating an indication of the one or more memory devices, and the fourth terminal is associated with communicating a clock signal.

13. The memory system of claim 1, wherein the plurality of first terminals is associated with a separate command address (SCA) interface and the plurality of second terminals is associated with an open NAND flash interface (ONFI).

14. A memory system, comprising:
memory interface circuitry operable to couple with one or more memory devices; and
processing circuitry coupled with the memory interface circuitry and configured to cause the memory system to:
receive, at the memory interface circuitry, a first command via a plurality of first terminals to write an indication of the one or more memory devices, the plurality of first terminals associated with a first quantity of terminals;
write the indication of the one or more memory devices to the memory interface circuitry based at least in part on receiving the first command;
receive, at the memory interface circuitry, a second command via the plurality of first terminals to configure the memory interface circuitry to generate a data sequence based at least in part on writing the indication;
write a first portion of the data sequence to a buffer of the memory interface circuitry based at least in part on generating the data sequence;
output, from the buffer via a plurality of second terminals, the first portion of the data sequence to the one or more memory devices based at least in part on determining that an amount of data written to the buffer satisfies a threshold; and
write a second portion of the data sequence to the buffer based at least in part on generating the data sequence and transferring the first portion.

15. The memory system of claim 14, wherein the processing circuitry is further configured to cause the memory system to:
receive, at the memory interface circuitry via the plurality of first terminals, a third command to enable a mapping associated with a header cycle type of the second command and one or more functions of the memory interface circuitry, wherein receiving the second command is based at least in part on enabling the mapping.

16. The memory system of claim 14, wherein the processing circuitry is further configured to cause the memory system to:
receive, at the memory interface circuitry via the plurality of first terminals, a third command to determine whether the data sequence was stored to the one or more memory devices; and
outputting, from the memory interface circuitry via the plurality of first terminals, an indication that the data sequence be stored in response to receiving the third command.

17. The memory system of claim 14, wherein the processing circuitry is further configured to cause the memory system to:
receive, at the memory interface circuitry via the plurality of first terminals, a third command to perform an error evaluation of at least one of the one or more memory devices;
perform the error evaluation of the at least one of the one or more memory devices based at least in part on reading the data sequence from the at least one of the one or more memory devices; and
output a response to the third command based at least in part on performing the error evaluation.

18. The memory system of claim 17, wherein performing the error evaluation is configured to cause the memory system to:
generate a second data sequence based at least in part on a seed value; and
compare the second data sequence with the data sequence read from the at least one of the one or more memory devices to determine an error rate, wherein generating the data sequence is based at least in part on the seed value.

19. A system, comprising:
one or more memory devices;
a plurality of first terminals;
a plurality of second terminals;
a memory system controller coupled with the one or more memory devices and with the plurality of second terminals; and
memory interface circuitry coupled with the one or more memory devices and with the plurality of first terminals, the memory interface circuitry comprising a buffer and configured to:
receive, via the plurality of first terminals, a command to configure the memory interface circuitry to receive data associated with a write burst;
receive, via the plurality of first terminals during a first duration, a first portion of the data to write to the buffer;
receive, via the plurality of first terminals during a second duration after the first duration and, a second portion of the data to write to the buffer; and
output the first portion of the data and the second portion of the data from the buffer concurrently to at least one of the one or more memory devices based at least in part on determining that an amount of data written to the buffer satisfies a threshold.

20. The system of claim 19, wherein the memory interface circuitry is configured to bypass the memory system controller for communicating with the one or more memory devices.
